(19) United States
(12) Patent Application Publication
(10) Pub. No.: US 2014/0014165 A1
(43) Pub. Date: Jan. 16, 2014

(54) SOLAR BATTERY SYSTEM AND SOLAR BATTERY MODULE

(71) Applicants: Daisuke Echizenya, Tokyo (JP); Norihiro Watanabe, Tokyo (JP); Naoki Ito, Tokyo (JP); Atsushi Michimori, Tokyo (JP); Hiroo Sakamoto, Tokyo (JP)

(72) Inventors: Daisuke Echizenya, Tokyo (JP); Norihiro Watanabe, Tokyo (JP); Naoki Ito, Tokyo (JP); Atsushi Michimori, Tokyo (JP); Hiroo Sakamoto, Tokyo (JP)

(73) Assignee: Mitsubishi Electric Corporation, Tokyo (JP)

(21) Appl. No.: 14/009,390

(22) PCT Filed: Apr. 20, 2012
(86) PCT No.: PCT/JP2012/060755

§ 371 Date: Oct. 2, 2013

(51) Int. Cl. H01L 31/042

(52) U.S. Cl. CPC H01L 31/0422
USPC 136/251

(57) ABSTRACT

Each of solar battery modules includes a rectangular solar battery panel, and a holding member extending from an inner side of the solar battery panel to opposite short sides thereof in a direction parallel to a long side of the solar battery panel. A mount includes rod-like members, to which a row of short-side groups in which sets of short sides of the solar battery panels adjacent to each other are arranged in a direction along the short sides is fitted via the holding members. The holding members are bonded to a rear surface of the solar battery panel. The long side is equal to or longer than 1.3 meters, and the short side is equal to or longer than 0.9 meter. The solar battery panel includes a glass substrate having a total plate thickness of equal to or smaller than 2.5 millimeters.

### FIELD

The present invention relates to a solar battery system and a solar battery module.

### BACKGROUND

Conventionally, structures for facilitating installation of a solar battery module have been proposed.

Patent Literature 1 describes a technique in which a slide member having an H shape in cross section and provided on a rear surface of a solar battery panel is slid and fitted to a channel-shaped guide member fixed on a mounting surface of a structural object, thereby fixing a solar battery module on the mounting surface of the structural object. According to Patent Literature 1, a solar battery module can be manufactured with a mechanical strength equal to conventional one, and construction and installation of the solar battery module are supposed to be considerably more facilitated than in conventional fixation by fastening with a fastener member.

Patent Literature 2 describes a technique in which a positioning piece of a solar battery panel to be fitted is inserted into a lower side of a solar battery panel already mounted to arrange and position the solar battery panel on a side of a connection piece of the already-mounted solar battery panel, and the connection piece is connected to a support rail with a fixing member, thereby fitting the solar battery panel. According to Patent Literature 2, the solar battery panel can be fitted while performing positioning at an accurate position, and thus fitting work is supposed to be easily achieved without requiring a long working time.

### CITATION LIST

### Patent Literatures

Patent Literature 1: Japanese Patent Application Laid-open No. 2005-175236
Patent Literature 2: Japanese Patent No. 2502921

### SUMMARY

### Technical Problem

According to the technique described in Patent Literature 1, because the solar battery module is mounted by fitting the guide member and the slide member to each other, a structure for installing the solar battery module is complicated as a whole, and the number of components of the structure is likely to increase, so that the installation cost tends to increase.

According to the technique described in Patent Literature 2, because the positioning piece and the connection piece are provided for each solar battery panel to install the solar battery module by connecting the connection piece to the support rail with the fixing member, a structure for installing the solar battery module is complicated as a whole, and the number of components of the structure is likely to increase, which increases the installation cost.

Meanwhile, a solar battery mount may be used for installing a plurality of solar battery modules. In this case, to withstand against a load such as a wind pressure assumed at the time of use, a solar battery system is installed by fitting a solar battery module designed to ensure the strength of a solar battery module alone to the solar battery mount designed to have a shape appropriate to receive sunlight. The solar battery mount is also designed to withstand against various types of load.

At this time, because the solar battery module is not designed exclusively for the solar battery mount, the number of components in the entire solar battery system is likely to increase, thereby increasing the installation cost. Particularly, when the solar battery module has a larger area and influences caused by pressure load increase, the structure of the mount tends to be complicated to prevent breakage of the solar battery module, thereby increasing the installation cost.

The present invention has been achieved to solve the above problems, and an object of the present invention is to provide a solar battery system and a solar battery module that can reduce the number of components, can suppress increase in the installation cost, and can reduce the production cost considerably.

### Solution to Problem

There is provided a solar battery system according to an aspect of the present invention including: a plurality of solar battery modules arranged two-dimensionally; and a mount that supports the solar battery modules, wherein each of the solar battery modules includes a rectangular solar battery panel, and a holding member that holds the solar battery panel, extending from an inner side of the solar battery panel to opposite short sides thereof in a direction parallel to a long side of the solar battery panel when seen through from a direction perpendicular to a principal surface of the solar battery panel, the mount includes a plurality of rod-like members, to which a row of short-side groups in which sets of short sides of the solar battery panels adjacent to each other are arranged in a direction along the short sides is fitted via the holding members, each of the holding members is bonded to a rear surface of the solar battery panel, the long side of the solar battery panel is equal to or longer than 1.3 meters, the short side of the solar battery panel is equal to or longer than 0.9 meter, and the solar battery panel includes a glass substrate having a total plate thickness of equal to or smaller than 2.5 millimeters.

### Advantageous Effects of Invention

According to the present invention, solar battery modules arranged along short sides of solar battery panels can be fitted by substantially one rod-like member while supporting the solar battery modules on both sides with a rod-like member. Accordingly, the number of rod-like members on a mount can be reduced, thereby enabling to reduce the number of components and suppress increase in the installation cost. Furthermore, even if the solar battery panel becomes larger, the solar battery panel can withstand against a large surface pressure acting on a light-receiving surface of the solar battery panel due to the stiffness of the holding member, and thus a thin glass can be used as a glass substrate. Accordingly, the size of the solar battery panel can be increased while realizing weight reduction, and the production cost of the solar battery module per area of the solar battery panel and per power generation amount can be reduced considerably.

### BRIEF DESCRIPTION OF DRAWINGS

FIG. 1 depicts a configuration of a solar battery system according to a first embodiment.

FIG. 2 depicts a configuration of a solar battery module according to the first embodiment.

FIG. 3 depicts a result of an analysis of a bonding position and a stress of a solar battery panel.

FIG. 4 depicts results of an analysis of bonding positions and stresses of a solar battery panel.

FIG. 5 depicts a configuration of a solar battery module according to a second embodiment.

FIG. 6 depicts a configuration of a solar battery system according to a third embodiment.

FIG. 7 depicts a configuration of a solar battery module according to the third embodiment.

FIG. 8 is a schematic diagram in which rear surfaces of solar battery panels according to the third embodiment are placed facing each other.

FIG. 9 depicts a configuration of a solar battery system according to a fourth embodiment.

FIG. 10 depicts a configuration of a solar battery module according to the fourth embodiment.

FIG. 11 depicts a configuration of a solar battery system according to a comparative example.

FIG. 12 depicts a configuration of a solar battery module according to the comparative example.

### DESCRIPTION OF EMBODIMENTS

Exemplary embodiments of a solar battery system according to the present invention will be explained below in detail with reference to the accompanying drawings. The present invention is not limited to the embodiments.

### First Embodiment

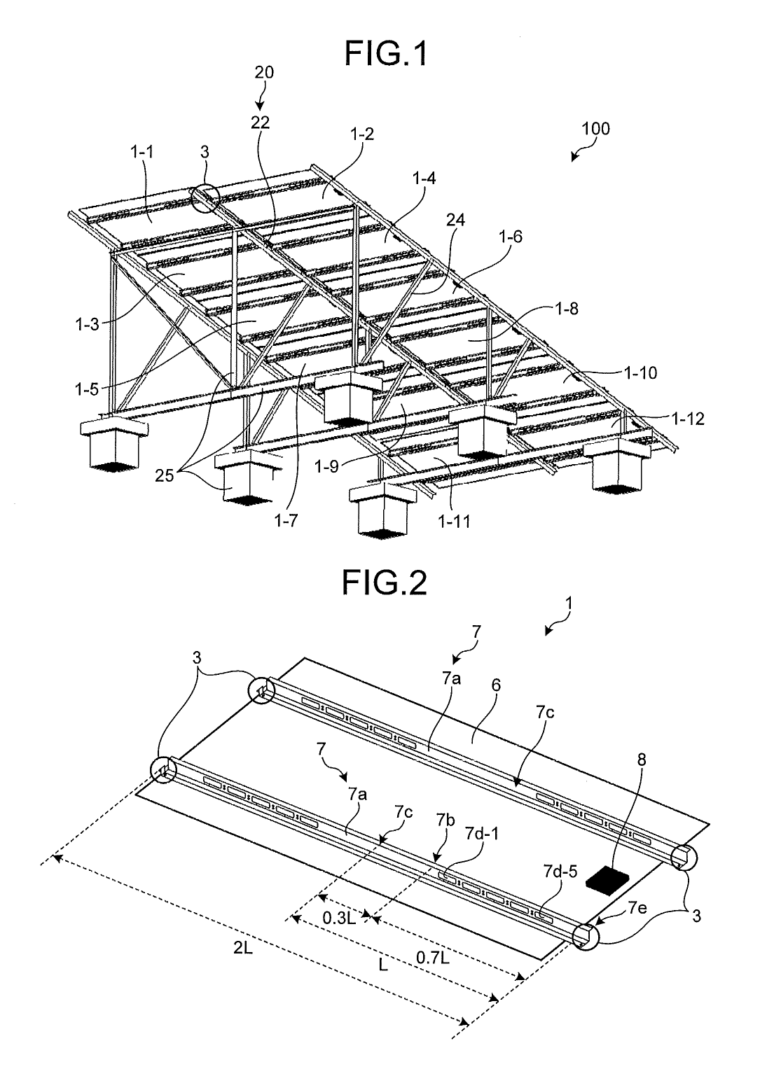

A solar battery system 100 according to a first embodiment is explained with reference to FIG. 1. FIG. 1 is a perspective view of a configuration of the solar battery system 100.

In the solar battery system 100, a plurality of solar battery modules 1 are mounted on a mounting surface (not shown) by using a solar battery mount 20.

In the case of a large solar battery system, many solar battery modules 1 are two-dimensionally arranged (to form a plurality of rows and a plurality of columns). FIG. 1 is a perspective view of two of the rows from an end thereof (two rows of solar battery modules 1-1 to 1-12) as viewed from a rear surface side. FIG. 2 is a perspective view of each solar battery module 1 according to the first embodiment, as viewed from the rear surface side opposite to a light receiving surface. In the solar battery system 100 shown in FIG. 1, the solar battery modules 1 shown in FIG. 2 are fitted to form the solar battery system.

In recent years, adoption of solar batteries as along with the importance of natural energy are increasing, and a photovoltaic facility, referred to as “mega solar”, in which several thousands or more of solar battery modules are mounted, has been constructed. To install a large quantity of solar battery modules, a structure of a solar battery mount suitable for power generation is also important. Particularly, the solar battery mount 20 having an inclination for efficiently receiving sunlight as shown in FIG. 1 can be used anywhere to install a solar battery system having high power generation efficiency if there is an open space. However, the installation cost is high because the solar battery mount is large as a base, and therefore a lower-cost structure has been desired.

The solar battery mount 20 and the solar battery module 1 need to withstand against a load assumed at the time of use. As specified by the JIS or the like, hardest loads are loads of a wind pressure by wind and accumulated snow, which are both pressures applied to a principal surface of a solar battery panel 6. The solar battery module 1 is designed to ensure the strength with respect to the pressure load alone, and the solar battery mount 20 that can withstand against the load is mounted in the solar battery system 100.

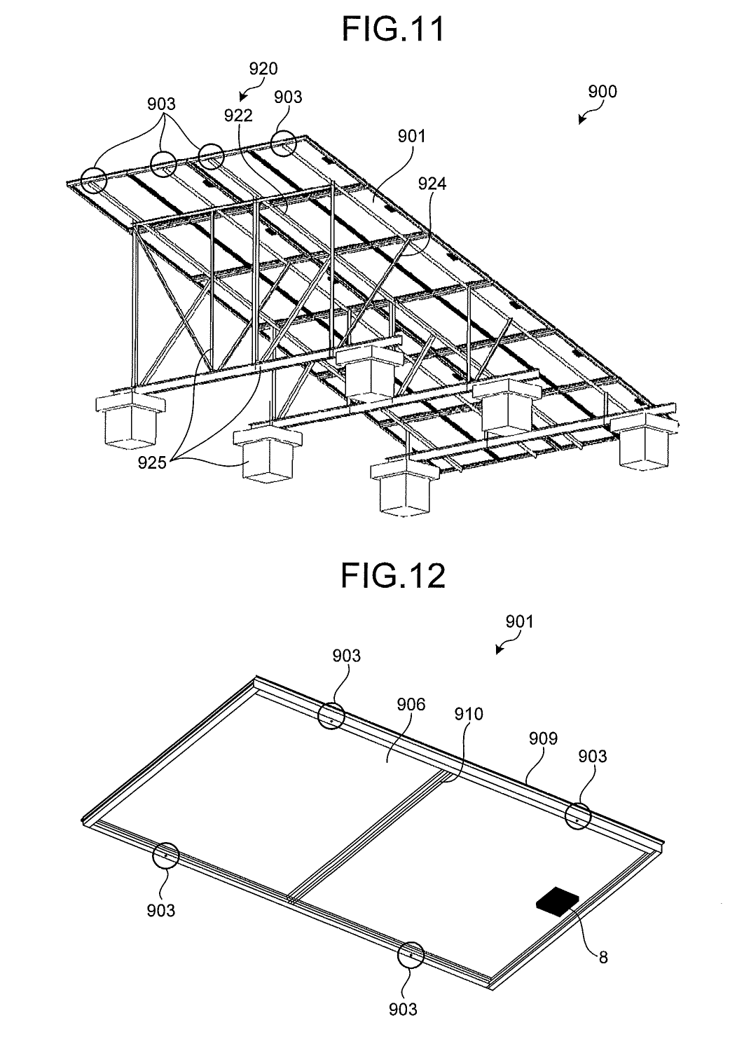

FIG. 11 depicts a configuration of a solar battery system 900 according to a comparative example. FIG. 12 depicts the configuration of a solar battery module 901 according to the comparative example. In the solar battery module 901, a solar battery panel 906, in which solar battery cells that generate power are joined to a glass substrate and sealed, is designed to withstand against the pressure load by fitting a frame 909 to four sides of the panel in the same manner as a window frame.

However, as the solar battery panel 906 becomes large to reduce the production cost, influences caused by the pressure load increase, and it is becoming difficult to ensure a sufficient strength only by being held by the four-side frames 909. Therefore, in the solar battery module 901, a support frame 910 is added between two long-side frames 909 facing each other on the inner side of the solar battery panel 906, that is, on the rear surface thereof. When the solar battery panel is small, much flexibility is provided for points 903 at which the frames 909 of the solar battery module 901 are connected to a solar battery mount 920. However, when the solar battery panel 906 is large, the connection points are limited to inner positions from the ends of the long-side frames 909 to decrease the influences caused by the pressure load.

That is, it is difficult to fix the solar battery panel on the sides of the short-side frames 909 because the short-side frames 909 that can withstand against a bending moment due to a large surface pressure need to be manufactured, which is costly. Because the additional support frame 910 is fitted between the two long-side frames 909 facing each other to maximize the cost-effectiveness (for example, to shorten the length), the load of the long-side frames 909 increases, and thus the load of the long-side frames 909 needs to be decreased. Accordingly, in the solar battery system 900 shown in FIG. 11, each of the solar battery modules 901 arranged along the short sides of the solar battery panels 906 is fitted to two longitudinal members 922 respectively extending in a direction along the rear surfaces of the solar battery panels 906 and in a direction perpendicular to the long-side frames 909. Furthermore, in the solar battery mount 920, the respective longitudinal members 922 are supported by a base member 925 and a diagonal member 924.

In contrast, the solar battery system 100 according to the present embodiment includes the solar battery mount 20 in which adjacent short sides of the solar battery modules 1 are fitted to one longitudinal member 22. Many solar battery modules 1, in each of which holding members 7 are placed on the solar battery module surface in a direction parallel to the long sides of the rectangular solar battery panel 6 as shown in FIG. 2, are arranged as shown in FIG. 1.

Specifically, as seen through from a direction perpendicular to the principal surface (for example, the light receiving surface) of the solar battery panel 6, the holding member 7 extends to protrude from the inner side of the solar battery panel 6 to the opposite short sides, respectively, in a direction parallel to the long side of the solar battery panel 6. The holding member 7 is bonded to the rear surface (the principal surface opposite to the light receiving surface) of the solar battery panel 6. A point 3 at which the holding member 7 of the solar battery module 1 is connected to the solar battery mount 20 is a portion protruding on the short side in the holding member 7. The solar battery mount 20 has the longitudinal member (rod-like member) 22, to which a row of short-side group is fitted via the holding members 7. In the row of short side group, a set of short sides of the solar battery panels 6 adjacent to each other are arranged in a direction along the short side of the solar battery panel 6. The longitudinal member 22 is provided to each of short side groups in a plurality of rows. The longitudinal members 22 are supported by base members 25 and diagonal members 24. Accordingly, in the solar battery system 100, the respective solar battery modules 1-2, 1-4, 1-6, 1-8, 1-10, and 1-12 arranged along the short side of the solar battery panel 6 are fitted substantially by one longitudinal member 22 per one solar battery module (only the endmost row of a plurality of rows is fitted by two longitudinal members 22), while being supported by the longitudinal members 22 on the both sides. The same thing applies, for example, to the respective solar battery modules 1-1, 1-3, 1-5, 1-7, 1-9, and 1-11 arranged along the short side of the solar battery panel 6.

As an example, when the solar battery system 100 in which ten rows of solar battery modules 1 are arranged transversely is to be manufactured for a large-scale power generation facility, 20 longitudinal members 922 are required according to the method shown in FIG. 12. On the other hand, 11 longitudinal members 22 are required according to the method of the present embodiment shown in FIG. 1 to obtain the solar battery mount 20. As the number of longitudinal members 22 decreases, the number of diagonal members 24 and base members 25 that support the longitudinal members 22 decreases. Accordingly, the number of members and the number of operations can be decreased, thereby enabling to reduce the cost considerably.

When it is assumed that the solar battery panel 6 is fitted to the longitudinal member 22 not on the short side but at the center, the solar battery panel 6 can be fitted by one longitudinal member per one solar battery module 1 also with respect to the endmost row of the plurality of rows. Therefore, one longitudinal member can be further decreased as a whole. However, because the solar battery panels 6 adjacent to each other are not joined, support stiffness of the base member 25 tends to be insufficient in the solar battery mount 20, and therefore the base member 25 itself needs to be stiffened so that the base member 25 does not fall down, or joined by a mount member in a different transverse direction.

On the other hand, in the present embodiment, in the solar battery system 100, because the solar battery panels 6 adjacent to each other are joined by the longitudinal member 22 via the holding members 7, support stiffness of the base member 25 can be reinforced via the longitudinal member 22 by the stiffness of the holding member 7, thereby enabling to prevent the base member 25 from falling down.

As described above, in the first embodiment, the solar battery system 100 includes the solar battery module 1 having a large area in which the holding members 7 are placed on the solar battery module surface in the direction parallel to the long side of the solar battery panel 6, and the solar battery mount 20 in which the short sides of the solar battery panels 6 that are adjacent to each other when a number of solar battery modules 1 are arranged are fitted to one longitudinal member 22. That is, as seen through from the direction perpendicular to the principal surface (for example, the light receiving surface) of the solar battery panel 6, the holding members 7 extend to protrude from the inner side of the solar battery panel 6 to the opposite short sides, respectively, in the direction parallel to the long side of the solar battery panel 6. Furthermore, a row of short side group in which the set of short sides of the solar battery panels 6 adjacent to each other are arranged in the direction along the short side of the solar battery panel 6 is fitted to the longitudinal member 22 via the holding members 7. Accordingly, the respective solar battery modules 1-2, 1-4, 1-6, 1-8, 1-10, and 1-12 arranged along the short side of the solar battery panel 6 are fixed substantially by one longitudinal member 22 per one solar battery module (only the endmost row of the plurality of rows is fixed by two longitudinal members 22), while being supported by the longitudinal members 22 on the both sides. Therefore, the number of longitudinal members 22 in the solar battery mount 20 can be considerably reduced than the conventional solar battery module, while using the solar battery module 1 having the large area, and the number of components can be reduced as a whole, and increase in the installation cost can be suppressed.

In the first embodiment, the holding members 7 are bonded to the rear surface of the solar battery panel 6 in the direction parallel to the long side. With this configuration, a boxed frame of the solar battery module is not required, thereby enabling to decrease the number of members corresponding to deletion of the short-side frame and the added support frame. Accordingly, the solar battery module can be manufactured at a low cost. As a result, the solar battery system can be manufactured at a low cost.

In the first embodiment, the holding member 7 is directly bonded to the rear surface of the solar battery panel 6. However, the holding member 7 can be bonded to the rear surface of the solar battery panel 6 via a spacer or the like put therebetween. An adhesive to be used is not limited. Incidentally, a silicon adhesive is suitable from the viewpoint that the solar battery system is used outside over a long period of time and due to a difference in coefficient of thermal expansion between the solar battery panel 6 and the holding member 7.

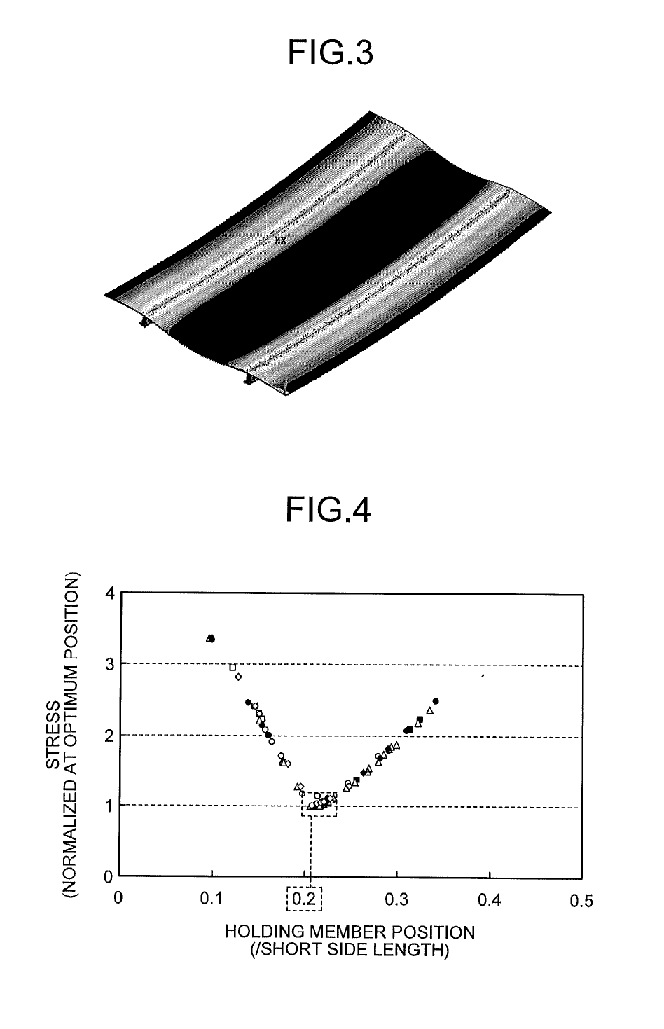

In the respective solar battery modules 1, as shown in FIG. 2, when two holding members 7 are provided, the respective holding members 7 can be bonded at positions where the short side of the solar battery panel 6 is divided in a ratio of 1:3:1 as a reference. In this connection, the present inventors conducted analysis of a bonding position and the stress of the solar battery panel. The result thereof is shown in FIGS. 3 and 4. That is, it was indicated in the analysis result obtained by the present inventors (for example, the graph in FIG. 4) that the stress applied to, for example, the light receiving surface of the solar battery panel 6 can be efficiently reduced (for example, to the minimum) by setting the respective holding members 7 at a position of, for example, 0.2 times the length of the short side, that is, by providing the holding members 7 at positions where the short side is divided in the ratio of 1:3:1. The position is only a reference, and an allowable error of, for example, about 10% can be provided according to design requirements.

In the respective solar battery modules 1, although not shown in the drawings, when three holding members 7 are provided, the respective holding members 7 can be bonded at positions where the short side of the solar battery panel 6 is divided in a ratio of 3:7:7:3 as a reference. The present inventors conducted analysis of the bonding position and the stress of the solar battery panel also for this case, although not shown in the drawings. That is, it was indicated in the analysis result obtained by the present inventors that the stress applied to, for example, the light receiving surface of the solar battery panel 6 can be efficiently reduced (for example, to the minimum) by positioning the respective holding members 7 at the positions where the short side of the solar battery panel 6 is divided in the ratio of 3:7:7:3. The position is only a reference, and an allowable error of, for example, about 10% can be provided according to design requirements.

Furthermore, the present inventors conducted analysis for a case where the size of the solar battery panel 906 was increased in the configuration of the comparative examples shown in FIGS. 11 and 12. As a result, although not shown in the drawings, it became clear that, when the long side of the solar battery panel 906 became longer than 1.3 meters, it was difficult to fix the solar battery panel 906 on the short side.

On the other hand, analysis was conducted also for a case where the size of the solar battery panel 906 is increased in the configuration of the present embodiment. As a result, although not shown in the drawings, it was confirmed that the effect of the present embodiment was obtained also by the solar battery module 1 in which the long side of the solar battery panel 6 shown in FIG. 2 was longer than 1.3 meters. For example, in the conventional solar battery module 901 shown in FIG. 12 in which a reinforced glass having a plate thickness of 3.2 millimeters was used as a substrate, when the long side of the solar battery panel 6 became 1.6 meters, it became clear that when a surface pressure of 5400 Pascal was applied in a state where the short side was fixed, the performance as the solar battery was affected. That is, when the long side of the solar battery panel 6 was longer than 1.3 meters, specifically, longer than 1.6 meters, it was confirmed that such an effect was obtained that the solar battery panel 6 can be fixed on the short side although it was difficult in the configuration of the comparative examples shown in FIGS. 11 and 12. Accordingly, the production cost per area and per amount of power generation in the solar battery panel can be reduced by increasing the size of the solar battery panel.

As a result of the analysis conducted by the present inventors, in the configuration of the comparative examples shown in FIGS. 11 and 12, it became clear that when the short side of the solar battery panel 906 became equal to or longer than 0.9 meter, it was difficult to withstand against a large surface pressure only by the four-side frames 909 of the solar battery panel 906, and the added support frame 910 is required.

On the other hand, according to the analysis conducted by the present inventors, it was confirmed that when the short side of the solar battery panel 6 was equal to or longer than 0.9 meter, such an effect was obtained that the solar battery panel 6 was able to withstand against the large surface pressure although it was difficult in the configuration of the comparative examples shown in FIGS. 11 and 12. Accordingly, the production cost per area and per amount of power generation in the solar battery panel can be reduced by increasing the size of the solar battery panel.

Further, as a result of the analysis conducted by the present inventors, it was confirmed that, in the configuration of the comparative examples shown in FIGS. 11 and 12, when the total plate thickness of the glass substrate in the solar battery panel 906 became equal to or less than 2.5 millimeters, double deformation occurred with respect to the conventional glass substrate having a plate thickness of 3.2 millimeters. Because of this, the deformation due to the surface pressure applied to, for example, the light receiving surface of the solar battery panel 906 is too large to hold the solar battery panel 906 by the four-side frames without the support frame 910, and the solar battery panel 906 may fall off from the frame 909. Therefore, the number of components needs to be increased, for example, the support frame 910 needs to be added, as measures against falling off.

In this connection, according to the analysis conducted by the present inventors, it was confirmed that the effect of the present embodiment was obtained even when the total plate thickness of the glass substrate in the solar battery panel 6 was equal to or less than 2.5 millimeters. That is, it was confirmed that when the total plate thickness of the glass substrate in the solar battery panel 6 was equal to or less than 2.5 millimeters, such an effect was obtained that the solar battery panel 6 withstood against the surface pressure applied to the light receiving surface of the solar battery panel 6 although it was difficult in the configuration of the comparative examples shown in FIGS. 11 and 12. The glass substrate can be formed by one glass substrate or two glass substrates overlapped on each other. Accordingly, a thin glass can be used, and the production cost of the solar battery panel can be reduced, thereby enabling to realize weight reduction of the solar battery panel.

In the first embodiment, the holding member 7 is bonded to the rear surface of the solar battery panel 6. The solar battery panel 6 has the glass substrate having the long side of 1.3 meters or longer, the short side of 0.9 meter or longer, and the total plate thickness of 2.5 millimeters or less. Thus, due to the stiffness of the holding member 7, the solar battery module can withstand against the large surface pressure applied to the light receiving surface of the solar battery panel 6 even if the size of the solar battery panel 6 is increased, and thin glass can be used as the glass substrate. Accordingly, size increase and weight reduction of the solar battery panel 6 can be realized simultaneously, and the production cost of the solar battery module 1 per area and per amount of power generation of the solar battery panel 6 can be considerably reduced.

In the first embodiment, the solar battery mount 20 having an inclination, on which the solar battery modules 1 are mounted, has been explained as an example. However, it is clear that the concept of the present embodiment can be applied to a solar battery mount having no inclination, on which a plurality of solar battery modules 1 are mounted, so long as the solar battery mount includes a mount material corresponding to the longitudinal member 22. As an example, a vertical installation mount to be installed on the side of a building, a mount to be fitted to a solar tracking device, a mount to be assembled on the roof, and the like can be mentioned.

The holding member 7 to be bonded on the rear surface of the solar battery panel 6 can be a rail manufactured, for example, by folding plate-like metal. As a material of the rail, corrosion-resistant metal such as stainless steel and aluminum, and a zinc-coated steel plate are suitable in order to endure long-term outside use. Furthermore, an extruded aluminum member or a plastic member can be used instead of the folded member, so long as the strength thereof is maintained.

As shown in FIG. 2, it is useful to bore a hole in a rail side surface of the holding member 7 for weight saving. That is, the holding member 7 can have a plurality of holes on a side surface 7a facing the long side of the solar battery panel 6. In this case, when the hole for weight saving is bored avoiding near the central part on the rear surface of the solar battery panel 6 as shown in FIG. 2, influences caused by deterioration of the strength due to weight saving can be reduced. Because the stress is particularly high in the 30% vicinity of a central part 7c, influences caused by deterioration of the strength due to weight saving can be reduced by avoiding this area. Because the stress is particularly high in the 30% vicinity of the central part 7c, the influences of deterioration of the strength can be reduced by avoiding this area. For example, the right half of the holding member 7 on the lower side in FIG. 2 is explained as an example. When the whole length of the holding member 7 is assumed to be 2L, the right portion of the holding member 7 from the central part 7c has a length of L, half the length of 2L. At this time, the length from the central part 7c to a boundary portion 7b of the area in the 30% vicinity of the central part 7c is 0.3L. A plurality of holes 7d-1 to 7d-5 are provided in an area having a length of 0.7L from the boundary portion 7b to an end 7e. In other words, each of the holes 7d-1 to 7d-5 is provided at a position away from the central part 7c by 30% or more of the length from the central part 7c to the end 7e on the side surface 7a of the holding member 7.

Because the stress is likely to concentrate in the area in the 30% vicinity of the central part 7c in the holding member 7, when each hole is provided in the area in the 30% vicinity of the central part 7c, the stiffness of the holding member 7 per unit stress applied to the holding member 7 sharply decreases as it is considered for each portion in the holding member 7. Therefore, it becomes difficult to realize the effect that “due to the stiffness of the holding member 7, the solar battery module can withstand against the large surface pressure applied to the light receiving surface of the solar battery panel 6 even if the size of the solar battery panel 6 is increased”.

The hole can function as a handle at the time of carrying the solar battery module 1, and can be used for fixing a cable that connects the solar battery modules 1 at the time of installation. It is desired that the size of each hole is at least 5 centimeters in a width direction.

When the size of each hole is smaller than 5 centimeters in the width direction, it becomes difficult to insert four fingers of a worker at the time of carrying the solar battery module 1, and the convenience as the handle decreases.

As shown in FIG. 2, a power extraction unit 8 can be arranged between the holding members 7 on the rear surface of the solar battery panel 6.

### Second Embodiment

A solar battery system 100i according to a second embodiment is explained next. Features different from those of the first embodiment are mainly explained below.

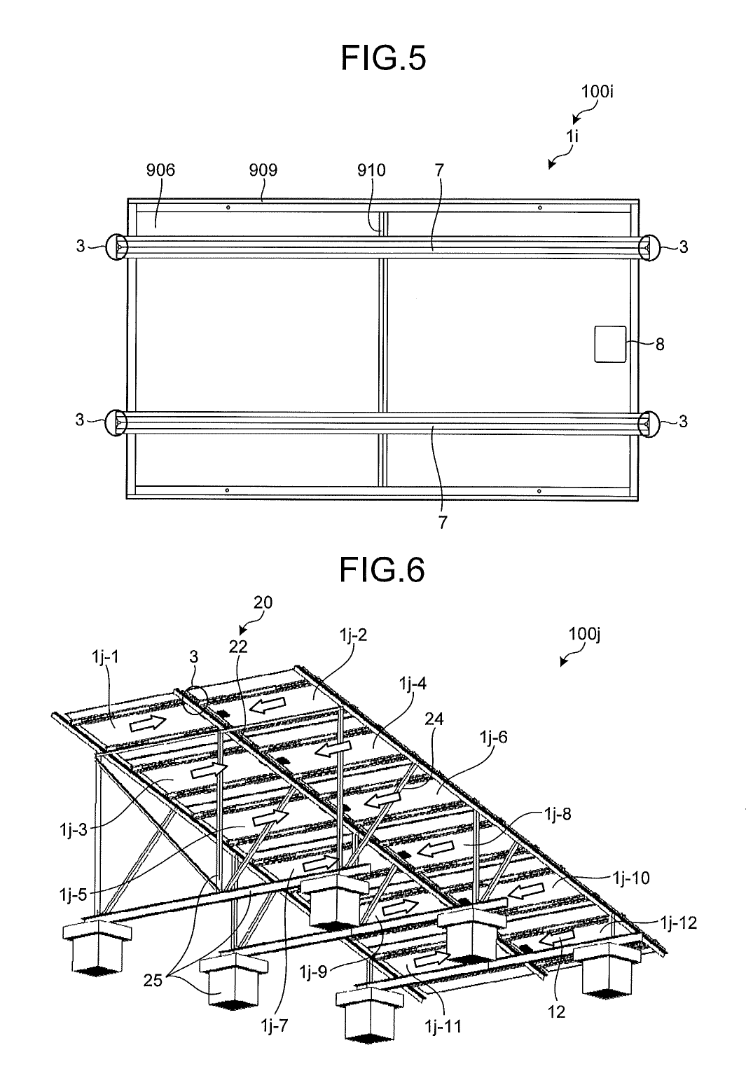

In the solar battery system 100i according to the second embodiment, as shown in FIG. 5, a solar battery module in which the holding members 7 are fitted to the solar battery module 901 so that the solar battery modules 901 can be joined on the short sides is used as a solar battery module 1i. For example, two holding members 7 are bonded to two short-side frames 909 facing each other. In this case, because the solar battery panel 906 is held by the four-side frames 909, the support frame 910, and the holding members 7, the strength at the time of holding the solar battery panel 906 can be further improved. Even when the size of the solar battery panel 906 is further increased, the solar battery panel 906 can withstand against the large surface pressure applied to the light-receiving surface of the solar battery panel 906, and the production cost per area and per amount of power generation of the solar battery panel 906 can be reduced.

The number of longitudinal member 22 of the solar battery mount 20 (see FIG. 1) can be considerably reduced than in the comparative example shown in FIG. 11 while using the solar battery module 1i having a large area. Therefore, the number of components as a whole can be reduced and increase in the installation cost can be suppressed.

The support frame 910 and the two long-side frames 909 facing each other can be omitted, while maintaining the strength at the time of holding the solar battery panel 906 to the same level as in the first embodiment. In this case, the solar battery module 1i can be manufactured at a low cost.

### Third Embodiment

A solar battery system 100j according to a third embodiment is explained next. Features different from those of the first embodiment are mainly explained below.

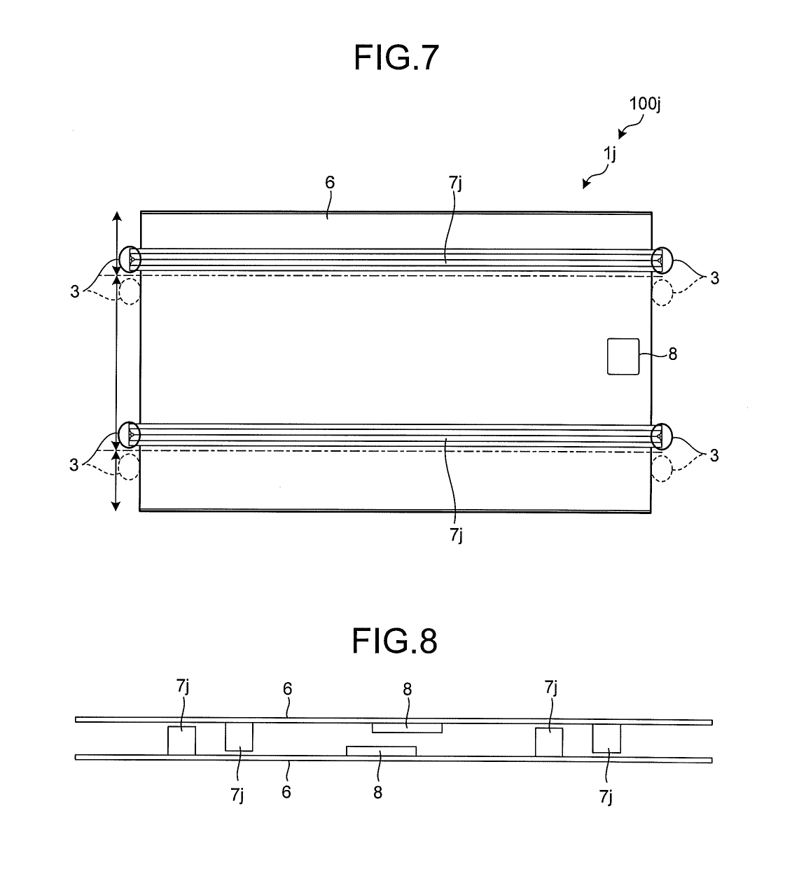

In the solar battery system 100j shown in FIG. 6, as shown in FIG. 7, the configuration of each solar battery module 1j is different from the configuration of the first embodiment. That is, in each solar battery system 1j, a plurality of holding members 7j are fixed to the solar battery panel 6 at positions shifted from reference positions indicated by a one-dot chain line approximately by half of a member width in the same direction (for example, in the upper direction in FIG. 7). The reference positions indicated by the one-dot chain line are positions determined by dividing the short side of the solar battery panel 6 in the ratio of 1:3:1. When two holding members are provided, by providing the holding members at the positions determined by dividing the short side of the solar battery panel in the ratio of 1:3:1, the stress applied to, for example, the light receiving surface of the solar battery panel can be efficiently reduced (for example, to the minimum). When three holding members are provided, by providing the holding members at the positions determined by dividing the short side of the solar battery panel in the ratio of 3:7:7:3, the stress applied to, for example, the light receiving surface of the solar battery panel can be efficiently reduced.

In this case, as shown by the arrows in FIG. 6, the direction of solar battery modules 1j-1 and 1j-2, whose short sides are adjacent to each other, is reversed so, that the holding members 7j are placed alternately therebetween (see fitting points 3 of the solar battery modules 1j adjacent to each other, indicated by the broken line in FIG. 7). Accordingly, a plurality of solar battery modules 1j-1 to 1j-12 can be lined up and fitted. Accordingly, the solar battery system 100j with a favorable appearance can be manufactured.

FIG. 8 is a schematic diagram in which the rear surfaces of the solar battery panels 6 of the solar battery module 1j according to the third embodiment are placed facing each other. In this manner, because the holding members 7j are fixed to the rear surface of the solar battery panel 6, shifted from the reference position by about half of the member width in parallel in the same direction, the rear surfaces of the solar battery panels 6 are caused to face each other and stored such that protrusions of the holding members 7j meshed with each other. Accordingly, the height at the time of storage can be made approximately half without changing the area, thereby enabling to improve carriability.

The holding member 7j can be fixed to the solar battery panel 6 at positions shifted from the reference positions indicated by the one-dot chain line by half of the member width or more in the same direction (for example, in the upper direction in FIG. 7). Also in this case, the rear surfaces of the solar battery panels 6 can be caused to face each other and stored such that protrusions of the holding members 7j meshed with each other. Accordingly, the height at the time of storage can be made approximately half, without changing the area, thereby enabling to improve carriability.

### Fourth Embodiment

A solar battery system 100k according to a fourth embodiment is explained next. Features different from those of the third embodiment are mainly explained below.

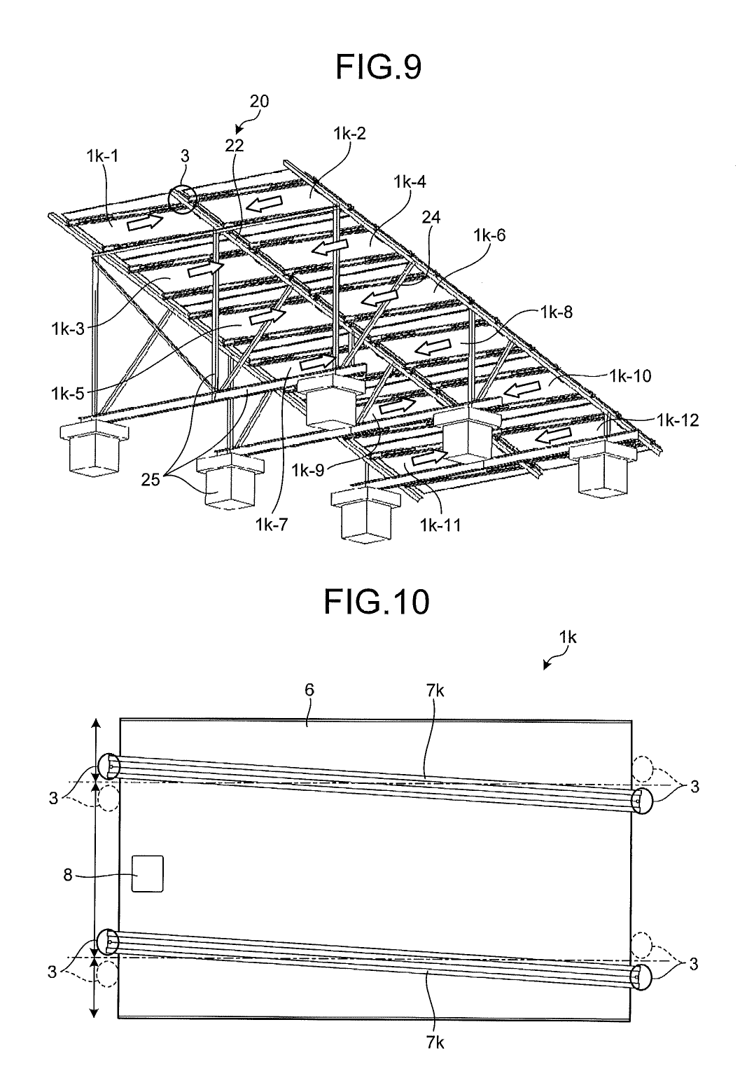

In the solar battery system 100k shown in FIG. 9, as shown in FIG. 10, the configuration of each solar battery module 1k is different from the configuration of the third embodiment. That is, in each solar battery system 1k, a plurality of holding members 7k are fixed to the solar battery panel 6 at positions rotated from reference positions indicated by a one-dot chain line (for example, in the clockwise direction in FIG. 10) such that the positions of the holding members 7k on the opposite short sides of the solar battery panel 6 are shifted approximately by half of a member width in the same direction. The reference positions indicated by the one-dot chain line are positions, for example, determined by dividing the short side of the solar battery panel 6 in the ratio of 1:3:1. When two holding members are provided, by providing the holding members at the positions determined by dividing the short side of the solar battery panel in the ratio of 1:3:1, the stress applied to, for example, the light receiving surface of the solar battery panel can be efficiently reduced (for example, to the minimum). When three holding members are provided, by providing the holding members at the positions determined by dividing the short side of the solar battery panel in the ratio of 3:7:7:3, the stress applied to, for example, the light receiving surface of the solar battery panel can be efficiently reduced.

In this case, as shown by the arrows in FIG. 9, the holding members 7k are placed alternately between solar battery modules 1k-1 and 1k-2, while directing the solar battery modules 1k-1 and 1k-2 with the short sides being adjacent to each other in the same direction (see fitting points 3 of the solar battery modules 1k adjacent to each other, indicated by the broken lines in FIG. 10). Accordingly, a plurality of solar battery modules 1k-1 to 1k-12 can be lined up and fitted. Accordingly, the solar battery system 100k with a favorable appearance can be manufactured.

As shown in FIG. 10, because the solar battery panels 6 of a plurality of solar battery modules 1k can be lined up and fitted, with the directions of the solar battery modules 1 being set in the same direction, even the solar battery module 1k in which the power extraction units 8 are arranged unsymmetrically can be installed.

The holding member 7k can be fixed to the solar battery panel 6 at positions rotated from reference positions indicated by a one-dot chain line (for example, in the clockwise direction in FIG. 10) such that the positions on the opposite short sides of the solar battery panel 6 are shifted approximately by half of the member width in the same direction. Also in this case, the holding members 7 are placed alternately between the solar battery modules 1k-1 and 1k-2, with short sides being adjacent to each other, while setting the solar battery modules 1k-1 and 1k-2 in the same direction (see fitting points 3 of the solar battery modules 1k adjacent to each other, indicated by the broken line in FIG. 10). In this case, the solar battery panels 6 of the solar battery modules 1k can be lined up and fitted. Accordingly, the solar battery system 100k with a favorable appearance can be manufactured.

### INDUSTRIAL APPLICABILITY

As described above, the solar battery system according to the present invention is useful for installation of a plurality of battery modules.

### REFERENCE SIGNS LIST

1, 1i, 1j, 1k, 901 solar battery module
3, 903 connection point
6 solar battery panel
7, 7j, 7k holding member
7a side surface
7b boundary portion
7c central part
7d-1 to 7d-5 hole
7e end
8 power extraction portion
20, 920 solar battery mount
22, 922 longitudinal member
24, 924 diagonal member
25, 925 base member
100, 100i, 100j, 100k, 900 solar battery system
909 frame
910 support frame

1. A solar battery system comprising:
a plurality of solar battery modules arranged two-dimensionally; and
a mount that supports the solar battery modules, wherein
each of the solar battery modules includes
a rectangular solar battery panel, and
a holding member that holds the solar battery panel, extending from an inner side of the solar battery panel to opposite short sides thereof in a direction parallel to a long side of the solar battery panel when seen through from a direction perpendicular to a principal surface of the solar battery panel,
the mount includes a plurality of rod-like members, to which a row of short-side groups in which sets of short sides of the solar battery panels adjacent to each other are arranged in a direction along the short sides is fitted via the holding members,
each of the holding members is bonded to a rear surface of the solar battery panel,
the long side of the solar battery panel is equal to or longer than 1.3 meters,
the short side of the solar battery panel is equal to or longer than 0.9 meter, and
the solar battery panel includes a glass substrate having a total plate thickness of equal to or smaller than 2.5 millimeters.

2. The solar battery system according to claim 1, wherein
each of the solar battery modules includes the holding member in plural, and
the holding members are bonded to the rear surface of the solar battery panel at positions determined by dividing the short side of the solar battery panel in a ratio of 1:3:1 as a reference when two holding members are provided, and at positions determined by dividing the short side of the solar battery panel in a ratio of 3:7:7:3 as a reference when three holding members are provided.

3. The solar battery system according to claim 1, wherein
each of the solar battery modules includes the holding member in plural, and
the holding members are fixed to the solar battery panel at positions shifted from reference positions by half of a member width or more in a same direction.

4. The solar battery system according to claim 1, wherein
each of the solar battery modules includes the holding member in plural,
the holding members are bonded to the rear surface of the solar battery panel at positions determined by dividing the short side of the solar battery panel in a ratio of 1:3:1 as a reference when two holding members are provided, and at positions determined by dividing the short side of the solar battery panel in a ratio of 3:7:7:3 as a reference when three holding members are provided, and
the holding members are fixed to the solar battery panel at positions shifted from reference positions by half of a member width or more in a same direction.

5. The solar battery system according to claim 1, wherein
each of the solar battery modules includes the holding member in plural, and
the holding members are fixed to the solar battery panel at positions rotated from reference positions in a same direction in such a manner that positions on opposite short sides of the solar battery panel are respectively shifted by half of a member width or more.

6. The solar battery system according to claim 1, wherein
each of the solar battery modules includes the holding member in plural,
the holding members are bonded to the rear surface of the solar battery panel at positions determined by dividing the short side of the solar battery panel in a ratio of 1:3:1 as a reference when two holding members are provided, and at positions determined by dividing the short side of the solar battery panel in a ratio of 3:7:7:3 as a reference when three holding members are provided, and
the holding members are fixed to the solar battery panel at positions rotated from reference positions in a same direction in such a manner that positions on opposite short sides of the solar battery panel are respectively shifted by half of a member width or more.

7. The solar battery system according to claim 1, wherein the holding member has a hole on a side surface facing the long side of the solar battery panel.

8. The solar battery system according to claim 7, wherein the hole is provided at a position away from a central part in the side surface of the holding member by at least 30% of a length of the holding member from the central part to an end.

9. A solar battery module comprising:
a rectangular solar battery panel; and
a holding member that holds the solar battery panel, extending from an inner side of the solar battery panel to opposite short sides thereof in a direction parallel to a long side of the solar battery panel when seen through from a direction perpendicular to a principal surface of the solar battery panel, wherein
the long side of the solar battery panel is equal to or longer than 1.3 meters,
the short side of the solar battery panel is equal to or longer than 0.9 meter, and
the solar battery panel includes a glass substrate having a total plate thickness of equal to or smaller than 2.5 millimeters.

10. The solar battery module according to claim 9, wherein
the solar battery module includes the holding member in plural, and
the holding members are bonded to a rear surface of the solar battery panel at positions determined by dividing the short side of the solar battery panel in a ratio of 1:3:1 as a reference when two holding members are provided, and at positions determined by dividing the short side of the solar battery panel in a ratio of 3:7:7:3 as a reference when three holding members are provided.

11. The solar battery module according to claim 9, wherein
the solar battery module includes the holding member in plural, and
the holding members are fixed to the solar battery panel at positions shifted from reference positions by half of a member width or more in a same direction.

12. The solar battery module according to claim 9, wherein
the solar battery module includes the holding member in plural,
the holding members are bonded to a rear surface of the solar battery panel at positions determined by dividing the short side of the solar battery panel in a ratio of 1:3:1 as a reference when two holding members are provided, and at positions determined by dividing the short side of the solar battery panel in a ratio of 3:7:7:3 as a reference when three holding members are provided, and
the holding members are fixed to the solar battery panel at positions shifted from reference positions by half of a member width or more in a same direction.

13. The solar battery module according to claim 9, wherein
the solar battery module includes the holding member in plural, and
the holding members are fixed to the solar battery panel at positions rotated from reference positions in a same direction in such a manner that positions on opposite short sides of the solar battery panel are respectively shifted by half of a member width or more.

14. The solar battery module according to claim 9, wherein
each of the solar battery modules includes the holding member in plural,
the holding members are bonded to a rear surface of the solar battery panel at positions determined by dividing the short side of the solar battery panel in a ratio of 1:3:1 as a reference when two holding members are provided, and at positions determined by dividing the short side of the solar battery panel in a ratio of 3:7:7:3 as a reference when three holding members are provided, and
the holding members are fixed to the solar battery panel at positions rotated from reference positions in a same direction in such a manner that positions on opposite short sides of the solar battery panel are respectively shifted by half of a member width or more.

15. The solar battery module according to claim 9, wherein the holding member has a hole on a side surface facing the long side of the solar battery panel.

16. The solar battery module according to claim 15, wherein the hole is provided at a position away from a central part in the side surface of the holding member by at least 30% of a length of the holding member from the central part to an end.
